(19) United States
(12) Patent Application Publication
(10) Pub. No.: US 2021/0005756 A1
(43) Pub. Date: Jan. 7, 2021

(54) THIN FILM TRANSISTOR AND MANUFACTURING METHOD THEREOF

(71) Applicant: Wuhan China Star Optoelectronics Technology Co., Ltd., Wuhan, Hubei (CN)

(72) Inventor: Pengbo QI, Wuhan (CN)

(21) Appl. No.: 16/344,904

(22) PCT Filed: Dec. 15, 2018
(86) PCT No.: PCT/CN2018/121361

§ 371 Date: Apr. 25, 2019

(30) Foreign Application Priority Data
Mar. 30, 2018 (CN) 201810294275.9

(51) Int. Cl. H01L 29/786; H01L 29/66

(52) U.S. Cl. CPC H01L 29/78621; H01L 29/78675; H01L 29/6675

(57) ABSTRACT

Provided are a thin film transistor and a manufacturing method thereof. The method includes: preparing a buffer layer, a polysilicon layer, a gate insulating layer and a gate electrode on a substrate, wherein the gate electrode is insulatively disposed above the polysilicon layer; performing N− ion doping to the polysilicon layer to form a lightly doped region; preparing a photoresist on the gate electrode and the gate insulating layer, and forming photoresist patterns on both sides of the gate electrode after etching; and performing N+ ion doping to the polysilicon layer with the photoresist patterns and the gate electrode as a photomask to form a heavily doped region.

### FIELD OF THE INVENTION

The present application relates to an array substrate manufacturing field, and more particular to a thin film transistor and a manufacturing method thereof.

### BACKGROUND OF THE INVENTION

LTPS (low temperature polysilicon) technology possesses an advantage of high carrier mobility and is suitable for fabricating high resolution displays. In the current LTPS technology, manufacturing a MOS (Metal Oxide Semiconductor) element requires a plurality of ion implantation processes, such as NCD, NP, N−, PP and etc.

In the LTPS technology of the prior art, first, a corresponding region of a corresponding NP portion (heavily doped region portion) is defined by the first photolithography process. N+ is doped into a polysilicon layer to form an NP portion, and a gate electrode is prepared. After the second photolithography process, N− is doped into the polysilicon layer to form LDD (lightly doped drain). This method needs high requirement for the alignment process of the NP portion and the gate electrode. Once the alignment of the NP portion and the gate electrode is deviated, the width of the LDD portion will become asymmetrical, resulting in a hot carrier effect in the MOS element. Ultimately, the final lighting forms an electrical Mura (light leakage). As shown in FIG. 1, the widths of the first lightly doped region portion 102 and the second lightly doped region portion 103 at two sides of the polysilicon layer 101 are uneven. The display effect is influenced.

Therefore, there is a need to provide a manufacturing method of a thin film transistor to solve the problems of the prior art.

### SUMMARY OF THE INVENTION

The present application provides a thin film transistor and a manufacturing method thereof, which can improve symmetry of a heavily doped region and a gate electrode to avoid an uneven width of a lightly doped region caused by a symmetrical deviation between the gate electrode and the heavily doped region for reducing process risk.

To solve the aforesaid problem, the technical solution provided by the present application is described as follows:

The present application provides a manufacturing method of a thin film transistor, including steps of:

Step S1, providing a substrate, and preparing a buffer layer, a polysilicon layer, a gate insulating layer and a gate electrode sequentially on the substrate, wherein the gate insulating layer is disposed above the polysilicon layer;

Step S2, performing N− ion doping to the polysilicon layer to form a lightly doped region in polysilicon layer corresponding to both sides of the gate electrode;

Step S3, preparing a photoresist on the gate electrode and the gate insulating layer, and forming photoresist patterns on the both sides of the gate electrode after etching; and

Step S4, performing N+ ion doping to the polysilicon layer with the photoresist patterns and the gate electrode as a photomask, and forming a heavily doped region in the lightly doped region corresponding to the photoresist patterns and the both sides of the gate electrode.

In the manufacturing method of the present application, the photoresist patterns on the both sides of the gate electrode are same in size and in shape.

In the manufacturing method of the present application, a material of the photoresist is tetraethyl orthosilicate.

In the manufacturing method of the present application, the photoresist corresponding to the gate electrode or the polysilicon layer is removed as etching the photoresist.

In the manufacturing method of the present application, the photoresist patterns on the both sides of the gate electrode respectively correspond to a first lightly doped region and a second lightly doped region, and a end of the first lightly doped region remote from the polysilicon layer and the gate electrode is formed as a first heavily doped region, and a end of the second lightly doped region remote from the polysilicon layer and the gate electrode is formed as a second heavily doped region.

In the manufacturing method of the present application, after Step S4, the manufacturing method further includes:

Step S5, removing the photoresist patterns; and

Step S6, preparing a source electrode and a drain electrode in predetermined areas.

For solving the aforesaid problems, the present application further provides a thin film transistor, including:

In the manufacturing method of the present application, after Step S4, the manufacturing method further includes:

a lightly doped region portion, disposed in a same layer as the polysilicon layer and disposed at both ends of the polysilicon layer;

a heavily doped region portion, disposed in a same layer as the polysilicon layer and disposed on a side of the lightly doped region portion remote from the polysilicon layer;

a gate electrode, insulatively disposed above the polysilicon layer;

a source electrode, electrically disposed on one end of the heavily doped region portion;

a drain electrode, oppositely disposed to the source electrode and electrically disposed on the other end of the heavily doped region portion;

wherein the lightly doped region portion is formed by performing N− ion doping to the polysilicon layer, and the heavily doped region portion is formed by performing N+ ion doping to the polysilicon layer; the lightly doped region portion includes a first lightly doped region portion and a second lightly doped region portion located at both sides of the polysilicon layer, and a width of the first lightly doped region portion is equal to a width of the second lightly doped region portion.

In the thin film transistor of the present application, the heavily doped region portion includes a first heavily doped region portion located on a side of the first lightly doped region portion remote from the polysilicon layer and the gate electrode and a second heavily doped region portion located on a side of the second lightly doped region portion remote from the polysilicon layer and the gate electrode.

In the thin film transistor of the present application, a width of the first heavily doped region portion is equal to a width of the second heavily doped region portion.

In the thin film transistor of the present application, a distance of the first heavily doped region portion from the polysilicon layer is equal to a distance of the second heavily doped region portion from the polysilicon layer.

For solving the aforesaid problems, the present application further provides a thin film transistor, including:

In the manufacturing method of the present application, after Step S4, the manufacturing method further includes:

a lightly doped region portion, disposed in a same layer as the polysilicon layer and disposed at both ends of the polysilicon layer;

a heavily doped region portion, disposed in a same layer as the polysilicon layer and disposed on a side of the lightly doped region portion remote from the polysilicon layer;

a gate electrode, insulatively disposed above the polysilicon layer;

a source electrode, electrically disposed on one end of the heavily doped region portion;

a drain electrode, oppositely disposed to the source electrode and electrically disposed on the other end of the heavily doped region portion;

wherein the lightly doped region portion includes a first lightly doped region portion and a second lightly doped region portion located at both sides of the polysilicon layer, and a width of the first lightly doped region portion is equal to a width of the second lightly doped region portion.

In the thin film transistor of the present application, the heavily doped region portion includes a first heavily doped region portion located on a side of the first lightly doped region portion remote from the polysilicon layer and the gate electrode and a second heavily doped region portion located on a side of the second lightly doped region portion remote from the polysilicon layer and the gate electrode.

In the thin film transistor of the present application, a width of the first heavily doped region portion is equal to a width of the second heavily doped region portion.

In the thin film transistor of the present application, a distance of the first heavily doped region portion from the polysilicon layer is equal to a distance of the second heavily doped region portion from the polysilicon layer.

The benefits of the present application are: compared with the manufacturing method of the thin film transistor according to the prior art, in the thin film transistor and the manufacturing method thereof according to the present application, the gate electrode pattern is first prepared, and then N− is doped into the polysilicon corresponding to both sides of the gate electrode to form the lightly doped region; then, a photoresist (TEOS, tetraethyl orthosilicate) is deposited on the gate electrode, and then is etched to form photoresist patterns at two sides of the gate electrode; N+ doping is performed with the photoresist patterns and the gate electrode as a photomask to form the heavily doped region in the lightly doped region corresponding to the photoresist patterns and the both sides of the gate electrode. The present application eliminates one photolithography process of a heavily doped region to save cost (the photolithography machine is the production cost bottleneck machine); meanwhile, the symmetry of the heavily doped region and the gate electrode is significantly improved to reduce the process risk.

### BRIEF DESCRIPTION OF THE DRAWINGS

In order to more clearly illustrate the embodiments of the present application and the prior art, the following figures will be described in the embodiments and the prior art are briefly introduced. It is obvious that the drawings are only some embodiments of the present application, those of ordinary skill in this field can obtain other figures according to these figures without paying the premise.

FIG. 1 is a structural view diagram of a thin film transistor manufactured by prior art;

FIG. 2 is a flowchart diagram of a manufacturing method of a thin film transistor provided by the present application;

FIG. 3a to FIG. 3d are manufacturing flowchart diagrams of a thin film transistor provided by the present application;

FIG. 4 is a structural diagram of a thin film transistor provided by the present application.

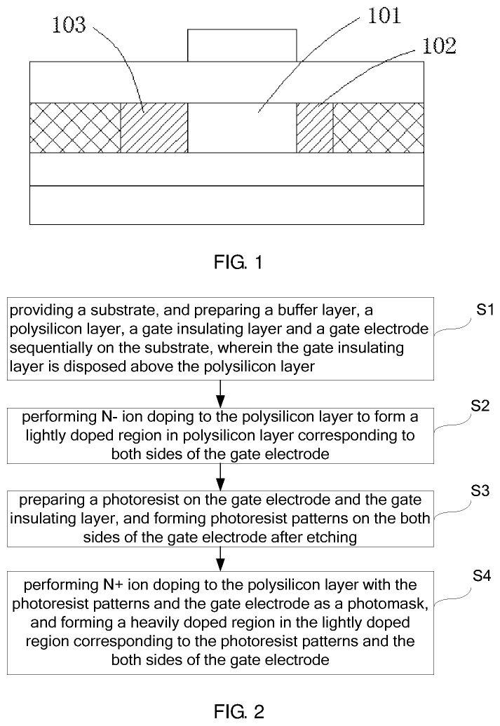

### DETAILED DESCRIPTION OF PREFERRED EMBODIMENTS

The following descriptions for the respective embodiments are specific embodiments capable of being implemented for illustrations of the present application with referring to appended figures. The terms of up, down, front, rear, left, right, interior, exterior, side, etcetera mentioned in the present application are merely directions of referring to appended figures. Thus, the used directional terms are used to describe and understand the present application, but the present invention is not limited thereto. In the figure, units with similar structures are denoted by the same reference numerals.

The present application is directed to solve the technical problem of the manufacturing method of the thin film transistor according to the prior art, in which the symmetry of the heavily doped region and the gate electrode may be easily to be deviated, thereby causing the width of the lightly doped region on the both sides of the polysilicon layer to be uneven, thereby affecting the display effect. This embodiment can solve the drawback.

FIG. 2 shows a flowchart diagram of a manufacturing method of a thin film transistor provided by the present application. The method comprises:

Step S1, providing a substrate, and preparing a buffer layer, a polysilicon layer, a gate insulating layer and a gate electrode sequentially on the substrate, wherein the gate insulating layer is disposed above the polysilicon layer;

Step S2, performing N− ion doping to the polysilicon layer to form a lightly doped region in polysilicon layer corresponding to both sides of the gate electrode;

Step S3, preparing a photoresist on the gate electrode and the gate insulating layer, and forming photoresist patterns on the both sides of the gate electrode after etching; and

Step S4, performing N+ ion doping to the polysilicon layer with the photoresist patterns and the gate electrode as a photomask, and forming a heavily doped region in the lightly doped region corresponding to the photoresist patterns and the both sides of the gate electrode.

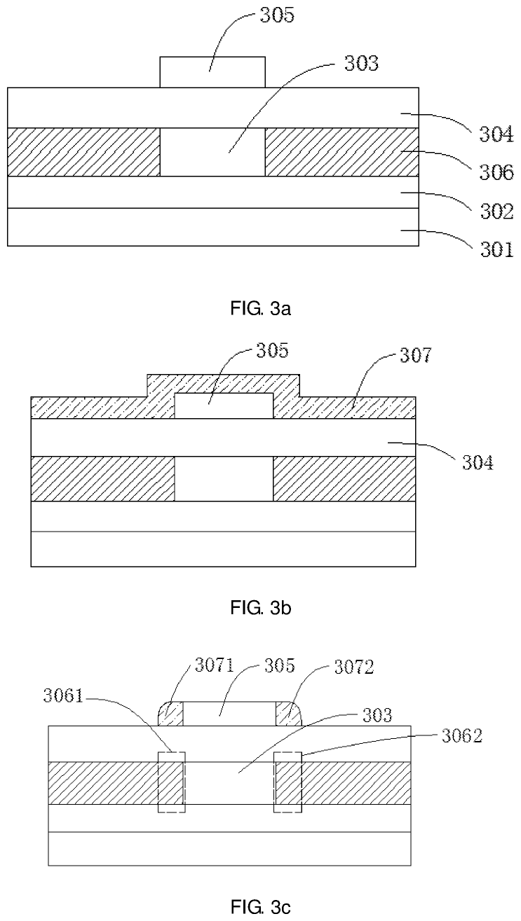

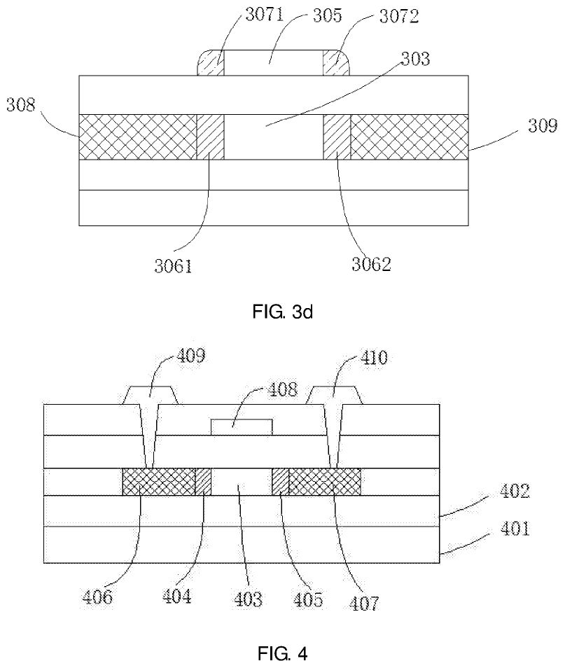

Specifically, FIG. 3a to FIG. 3d show manufacturing flowchart diagrams of a thin film transistor provided by the present application.

As shown in FIG. 3a, a substrate 301 is provided, and a buffer layer 302 is prepared on the substrate 301; a polysilicon layer 303 is prepared on the buffer layer 302; a gate insulating layer 304 is prepared on the polysilicon layer 303; and a gate electrode 305 is prepared on the gate insulating layer 304 corresponding to the polysilicon layer 303; N− ion doping is performed to the polysilicon layer 303 to form a lightly doped region 306 in the polysilicon layer 303 corresponding to both sides of the gate electrode 305.

As shown in FIG. 3b, a layer of photoresist 307 is deposited on a surface of the gate insulating layer 304 and the gate electrode 305. Preferably, the deposition is performed by chemical vapor deposition (CVD). Preferably, the photoresist 307 is a layer of tetraethyl orthosilicate (TEOS). The photoresist 307 is etched. Preferably, anisotropic etching is performed by dry etching to remove the photoresist 307 corresponding to the gate electrode 305 or correspondingly above the polysilicon layer to form corresponding photoresist patterns on the both sides of the gate electrode 305. The material of the photoresist 307 can also be other types.

As shown in FIG. 3c, the photoresist patterns correspond to the lightly doped region required for a thin film transistor process, and include a first photoresist pattern 3071 and a second photoresist pattern 3072 having the same size and the same shape on the both sides of the gate 305; the lightly doped region includes a first lightly doped region 3061 and a second lightly doped region 3062, which are respectively located at two sides of the polysilicon layer 303. The position of the first photoresist pattern 3071 corresponds to the first lightly doped region 3061, and the position of the second photoresist pattern 3072 corresponds to the second lightly doped region 3062.

As shown in FIG. 3d, N+ ion doping is performed to the polysilicon layer 303 with the first photoresist pattern 3071, the second photoresist pattern 3072 and the gate electrode 305 as a photomask to form the heavily doped region in the lightly doped region corresponding to the photoresist patterns and the both sides of the gate electrode 305. The heavily doped region includes a first heavily doped region 308 and a second heavily doped region 309. An end of the first lightly doped region 3061 remote from the polysilicon layer 303 and the gate electrode 305 is formed as the first heavily doped region 308, and an end of the second lightly doped region 3062 remote from the polysilicon layer 303 and the gate electrode 305 is formed as a second heavily doped region 309. A width of the first lightly doped region 3061 is equal to a width of the second lightly doped region 3062; a width of the first heavily doped region 308 is equal to a width of the second heavily doped region 309.

The manufacturing method of the thin film transistor further includes:

Step S5, removing the photoresist patterns; and

Step S6, preparing a source electrode and a drain electrode in predetermined areas.

The method for removing the photoresist patterns is the same as that of the prior art, and the method for preparing the source electrode and the drain electrode is also the same as the prior art, and details are not described herein.

The present application further provides a thin film transistor, which is preferably prepared by the aforesaid manufacturing method. As shown in FIG. 4, first, a substrate 401 is provided, and a buffer layer 402 is disposed on the substrate 401, and the thin film transistor is disposed on a surface of the buffer layer 402. The thin film transistor includes: a polysilicon layer 403; a gate electrode 408, insulatively disposed above the polysilicon layer 403; a lightly doped region portion, disposed in a same layer as the polysilicon layer 403 and disposed at both ends of the polysilicon layer 403; the lightly doped region portion includes a first lightly doped region portion 404 and a second lightly doped region portion 405 located on both sides of the polysilicon layer 403; a heavily doped region portion, disposed in a same layer as the polysilicon layer 403 and disposed on a side of the lightly doped region portion remote from the polysilicon layer 403; the heavily doped region portion includes a first heavily doped region portion 406 located on a side of the first lightly doped region portion 404 remote from the polysilicon layer 403 and the gate electrode 408 and a second heavily doped region portion 407 located on a side of the second lightly doped region portion 405 remote from the polysilicon layer 403 and the gate electrode 408; a source electrode 409, electrically disposed on the first heavily doped region portion 406; and a drain electrode 410, oppositely disposed to the source electrode 409 and electrically disposed on the second heavily doped region portion 407.

A width of the first lightly doped region portion 404 is equal to a width of the second lightly doped region portion 405; a width of the first heavily doped region portion 406 is equal to a width of the second heavily doped region portion 407. A distance of the first heavily doped region portion 406 from the polysilicon layer 403 is equal to a distance of the second heavily doped region portion 407 from the polysilicon layer 403. The lightly doped region portion is formed by performing N− ion doping to the polysilicon layer 403, and the heavily doped region portion is formed by performing N+ ion doping to the polysilicon layer 403.

Compared with the manufacturing method of the thin film transistor according to the prior art, in the thin film transistor and the manufacturing method thereof according to the present application, the gate electrode pattern is first prepared, and then N− is doped into the polysilicon corresponding to both sides of the gate electrode to form the lightly doped region; then, a photoresist (TEOS, tetraethyl orthosilicate) is deposited on the gate electrode, and then is etched to form photoresist patterns at two sides of the gate electrode; N+ doping is performed with the photoresist patterns and the gate electrode as a photomask to form the heavily doped region in the lightly doped region corresponding to the photoresist patterns and the both sides of the gate electrode. The present application eliminates one photolithography process of a heavily doped region to save cost (the photolithography machine is the production cost bottleneck machine); meanwhile, the symmetry of the heavily doped region and the gate electrode is significantly improved to reduce the process risk.

In summary, although the above preferred embodiments of the present application are disclosed, the foregoing preferred embodiments are not intended to limit the invention, those skilled in the art can make various kinds of alterations and modifications without departing from the spirit and scope of the present application. Thus, the scope of protection of the present application is defined by the scope of the claims.

What is claimed is:

1. A manufacturing method of a thin film transistor, including steps of:
Step S1, providing a substrate, and preparing a buffer layer, a polysilicon layer, a gate insulating layer and a gate electrode sequentially on the substrate, wherein the gate insulating layer is disposed above the polysilicon layer;
Step S2, performing N− ion doping to the polysilicon layer to form a lightly doped region in polysilicon layer corresponding to both sides of the gate electrode;
Step S3, preparing a photoresist on the gate electrode and the gate insulating layer, and forming photoresist patterns on the both sides of the gate electrode after etching; and
Step S4, performing N+ ion doping to the polysilicon layer with the photoresist patterns and the gate electrode as a photomask, and forming a heavily doped region in the lightly doped region corresponding to the photoresist patterns and the both sides of the gate electrode.

2. The manufacturing method according to claim 1, wherein the photoresist patterns on the both sides of the gate electrode are same in size and in shape.

3. The manufacturing method according to claim 1, wherein a material of the photoresist is tetraethyl orthosilicate.

4. The manufacturing method according to claim 1, wherein the photoresist corresponding to the gate electrode or the polysilicon layer is removed as etching the photoresist.

5. The manufacturing method according to claim 1, wherein the photoresist patterns on the both sides of the gate electrode respectively correspond to a first lightly doped region and a second lightly doped region, and a end of the first lightly doped region remote from the polysilicon layer and the gate electrode is formed as a first heavily doped region, and a end of the second lightly doped region remote from the polysilicon layer and the gate electrode is formed as a second heavily doped region.

6. The manufacturing method according to claim 1, wherein after Step S4, the manufacturing method further includes:
Step S5, removing the photoresist patterns; and
Step S6, preparing a source electrode and a drain electrode in predetermined areas.

7. A thin film transistor, including:
a polysilicon layer;
a lightly doped region portion, disposed in a same layer as the polysilicon layer and disposed at both ends of the polysilicon layer;
a heavily doped region portion, disposed in a same layer as the polysilicon layer and disposed on a side of the lightly doped region portion remote from the polysilicon layer;
a gate electrode, insulatively disposed above the polysilicon layer;
a source electrode, electrically disposed on one end of the heavily doped region portion;
a drain electrode, oppositely disposed to the source electrode and electrically disposed on an other end of the heavily doped region portion;
wherein the lightly doped region portion is formed by performing N− ion doping to the polysilicon layer, and the heavily doped region portion is formed by performing N+ ion doping to the polysilicon layer; the lightly doped region portion includes a first lightly doped region portion and a second lightly doped region portion located at both sides of the polysilicon layer, and a width of the first lightly doped region portion is equal to a width of the second lightly doped region portion.

8. The thin film transistor according to claim 7, wherein the heavily doped region portion includes a first heavily doped region portion located on a side of the first lightly doped region portion remote from the polysilicon layer and the gate electrode and a second heavily doped region portion located on a side of the second lightly doped region portion remote from the polysilicon layer and the gate electrode.

9. The thin film transistor according to claim 8, wherein a width of the first heavily doped region portion is equal to a width of the second heavily doped region portion.

10. The thin film transistor according to claim 8, wherein a distance of the first heavily doped region portion from the polysilicon layer is equal to a distance of the second heavily doped region portion from the polysilicon layer.

11. A thin film transistor, including:
a polysilicon layer;
a lightly doped region portion, disposed in a same layer as the polysilicon layer and disposed at both ends of the polysilicon layer;
a heavily doped region portion, disposed in a same layer as the polysilicon layer and disposed on a side of the lightly doped region portion remote from the polysilicon layer;
a gate electrode, insulatively disposed above the polysilicon layer;
a source electrode, electrically disposed on one end of the heavily doped region portion;
a drain electrode, oppositely disposed to the source electrode and electrically disposed on an other end of the heavily doped region portion;
wherein the lightly doped region portion includes a first lightly doped region portion and a second lightly doped region portion located at both sides of the polysilicon layer, and a width of the first lightly doped region portion is equal to a width of the second lightly doped region portion.

12. The thin film transistor according to claim 11, wherein the heavily doped region portion includes a first heavily doped region portion located on a side of the first lightly doped region portion remote from the polysilicon layer and the gate electrode and a second heavily doped region portion located on a side of the second lightly doped region portion remote from the polysilicon layer and the gate electrode.

13. The thin film transistor according to claim 12, wherein a width of the first heavily doped region portion is equal to a width of the second heavily doped region portion.

14. The thin film transistor according to claim 12, wherein a distance of the first heavily doped region portion from the polysilicon layer is equal to a distance of the second heavily doped region portion from the polysilicon layer.
